(19) United States
(12) Patent Application Publication
(10) Pub. No.: US 2026/0132538 A1
(43) Pub. Date: May 14, 2026

(54) MANUFACTURING METHOD OF GROUP-III NITRIDE SEMICONDUCTOR

(71) Applicants: TOYODA GOSEI CO., LTD., Kiyosu-shi (JP); The University of Osaka, Osaka (JP)

(72) Inventors: Taku FUJIMORI, Kiyosu-shi (JP); Yusuke MORI, Osaka (JP); Masayuki IMANISHI, Osaka (JP); Shigeyoshi USAMI, Osaka (JP)

(21) Appl. No.: 19/374,434

(22) Filed: Oct. 30, 2025

(30) Foreign Application Priority Data
Nov. 13, 2024 (JP) 2024-198130

(51) Int. Cl. C30B 19/02; C30B 29/40; H01L 21/02

(52) U.S. Cl. CPC C30B 19/02; C30B 29/406; H10P 14/3416

(57) ABSTRACT

Provided is a manufacturing method of a group-III nitride semiconductor capable of improving crystallinity. The manufacturing method of a group-III nitride semiconductor includes: an alkali metal coating step of covering a surface of an alkali metal of a solid form with a group-III metal; a mixed melt generation step of melting the alkali metal coated with the group-III metal along with the carbon to generate a mixed melt; and a crystal growth step of immersing a seed substrate in the mixed melt to grow a group-III nitride semiconductor on the seed substrate under an atmosphere containing nitrogen.

### CROSS-REFERENCE

This application claims priority to Japanese Patent Application No. 2024-198130 filed on November 13, 2024, the contents of which are fully incorporated herein by reference.

### TECHNICAL FIELD

The present invention relates to a manufacturing method of a group-III nitride semiconductor.

### BACKGROUND ART

A flux method has conventionally been known, in which a GaN substrate is immersed in a mixed melt of Ga and Na stored in a crucible to grow a GaN single crystal on the GaN substrate. However, when coming into contact with ambient air, Na reacts with oxygen, moisture, and the like such that impurities are generated on an outer layer, leading to insufficient growth of the GaN single crystal and degradation of crystallinity. To reduce such degradation of crystallinity, Patent Literature 1 discloses a mode that includes, in the course of producing the mixed melt of Ga and Na and after an Na melt is solidified in a crucible, supplying Ga while the inside of the crucible is heated to a temperature higher than or equal to a melting point of Ga and lower than a melting point of Na to cover a surface of solidified Na with molten Ga, so that exposure of Na to ambient air is reduced.

### PRIOR ART LITERATURE

### PATENT LITERATURE

[Patent Literature 1] JP-A-2012-214324

### SUMMARY

In the flux method, it is common practice to add carbon to the mixed melt to promote crystal growth and reduce formation of defective crystals. However, in the mode disclosed in Patent Literature 1, addition of carbon to the Na melt leads to degradation of wettability of the solidified Na by the Ga melt, making it difficult to cover the surface of Na with the Ga melt. Accordingly, there is room for improvement to improve crystallinity by reducing exposure of Na to ambient air while promoting crystal growth and reducing formation of defective crystals by means of carbon.

The present invention has been made in view of such problems and seeks to provide a manufacturing method of a group-III nitride semiconductor capable of improving crystallinity.

An aspect of the present invention is

a manufacturing method of a group-III nitride semiconductor, the method including:

an alkali metal coating step of covering a surface of an alkali metal of a solid form with a group-III metal;

a mixed melt generation step of melting the alkali metal coated with the group-III metal along with carbon to generate a mixed melt; and

a crystal growth step of immersing a seed substrate in the mixed melt to grow a group-III nitride semiconductor on the seed substrate under an atmosphere containing nitrogen.

In a manufacturing method of a group-III nitride semiconductor of the above aspect, the mixed melt is generated by covering the surface of the solid alkali metal with the group-III metal, which is thereafter melted along with carbon. Accordingly, wettability of the surface of the solid alkali metal by the melt of group-III metal is maintained and the surface of the alkali metal is coated with the group-III metal, so that the surface of the alkali metal is prevented from being exposed to ambient air. As a result, the surface of the alkali metal is prevented from reacting with oxygen, moisture, and the like in ambient air, and it is possible to improve crystallinity of a formed group-III nitride semiconductor.

As described above, according to the above aspect, it is possible to provide a manufacturing method of a group-III nitride semiconductor capable of improving crystallinity.

### BRIEF DESCRIPTION OF THE DRAWINGS

FIG. 1 is a flow diagram indicating a manufacturing method of a group-III nitride semiconductor in Embodiment 1;

FIG. 2 is a first conceptual diagram for describing a step of coating an alkali metal in Embodiment 1;

FIG. 3 is a second conceptual diagram for describing a step of coating an alkali metal in Embodiment 1;

FIG. 4 is a conceptual diagram for describing a step of adding carbon in Embodiment 1;

FIG. 5 is a conceptual diagram illustrating a state in which a seed substrate is not immersed in a mixed melt in Embodiment 1;

FIG. 6 is a conceptual diagram illustrating a state in which the seed substrate is immersed in the mixed melt in Embodiment 1;

FIG. 7 is a conceptual diagram of a jig and a crucible as viewed in top view in Embodiment 1;

FIG. 8 shows, in Embodiment 1, the part (a): a conceptual diagram of a seed substrate on which a plurality of seed crystals are formed, the part (b): a conceptual diagram of the seed substrate on which a plurality of initial nuclei are formed, the part (c): a conceptual diagram illustrating a state in which GaN single crystals are formed between the initial nuclei, and the part (d): a conceptual diagram illustrating a state in which a GaN single crystal is grown on a planarized crystal surface;

FIG. 9 is a plan view illustrating a configuration of a seed substrate in Embodiment 1;

FIG. 10 is a sectional view illustrating a configuration of the seed crystal in Embodiment 1 and is a sectional view that is perpendicular to the principal surface of the substrate;

FIG. 11 is a plan view illustrating a configuration of the seed crystal in Embodiment 1; and

FIG. 12 is a conceptual diagram for describing a step of coating an alkali metal in a modification.

### DETAILED DESCRIPTION

The carbon is preferably in powdered form. In this case, the surface area of carbon increases such that dispersion into melt of the alkali metal is facilitated, so that it is further possible to produce an effect of promoting crystal growth and an effect of reducing occurrence of defective crystals.

The alkali metal coating step preferably includes bringing a crucible in which melt of an alkali metal is stored to a temperature higher than or equal to a melting point of the group-III metal and lower than a melting point of the alkali metal such that the alkali metal is solidified in the crucible, and thereafter adding the group-III metal to the crucible to coat a surface of the alkali metal of a solid form with melt of the group-III metal. In this case, solidifying melt of the alkali metal in the crucible allows an upper surface of surfaces of the solid alkali metal to be a planar surface and makes it possible to cover a bottom surface and side surfaces by an inner bottom surface and inner side surfaces of the crucible. Accordingly, simply covering the upper surface of the solid alkali metal with the group-III metal makes it possible to block the entire area of the surfaces of the solid alkali metal from ambient air such that the surfaces of the alkali metal are prevented from reacting with oxygen, moisture, and the like in the ambient air, so that it is further possible to reduce degradation of crystallinity of a formed group-III nitride semiconductor.

The alkali metal coating step preferably includes adding the group-III metal to the crucible to coat a surface of the alkali metal of a solid form with melt of the group-III metal, and thereafter bringing the crucible to a temperature lower than a melting point of the group-III metal such that the group-III metal is solidified in a state in which the surface of the alkali metal is coated. In this case, the group-III metal is solidified in a state in which the surfaces of the solid alkali metal are coated with the melt of group-III metal in the crucible, so that the surfaces of the solid alkali metal can be reliably coated and kept in a coated state.

Preferably, a carbon addition step of adding carbon to the crucible after the alkali metal coating step is included, and the mixed melt generation step is performed after the carbon addition step. In this case, carbon is added after the group-III metal coating the surfaces of the solid alkali metal is solidified, and therefore, the wettability of the solid alkali metal by the group-III metal is not affected, so that the surfaces of the solid alkali metal can be reliably coated with the group-III metal and kept in a coated state.

In the carbon addition step, the carbon is preferably added in the crucible at a position excluding a position at which the seed substrate is to be immersed. In this case, when the seed substrate is to be immersed in the mixed melt, it is possible to facilitate dispersion of carbon into the mixed melt, so that it is further possible to produce an effect of promoting crystal growth and an effect of reducing occurrence of defective crystals.

### (Embodiment 1)

### 1. Outline of Flux Method

A manufacturing method of a group-III nitride semiconductor of Embodiment 1 is a method of manufacturing a group-III nitride semiconductor by using a flux method to grow a group-III nitride single crystal. The flux method refers to a method of epitaxially growing a group-III nitride semiconductor in a liquid phase by supplying and causing gas containing nitrogen to be dissolved in a mixed melt that contains an alkali metal, which acts as a flux, and a group-III metal, which is a raw material.

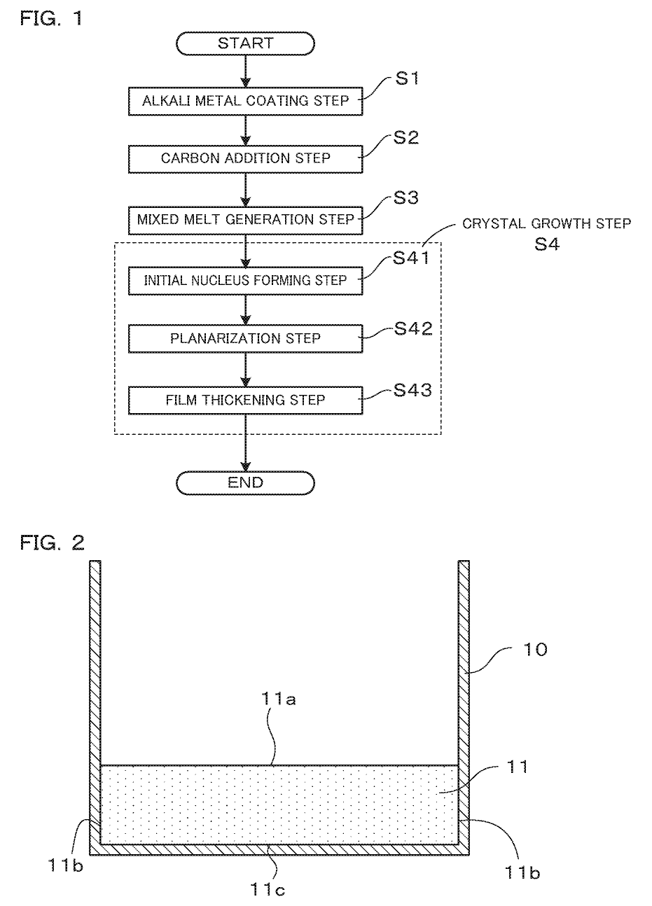

As indicated in FIG. 1, the manufacturing method of a group-III nitride semiconductor of Embodiment 1 includes an alkali metal coating step S1, a carbon addition step S2, a mixed melt generation step S3, and a crystal growth step S4. Each of the steps will now be described.

### 2. Alkali Metal Coating Step S1

In the alkali metal coating step S1, a surface of a solid alkali metal is covered with a group-III metal. The alkali metal may be Na, Li, K, and the like, and in the embodiment, Na is adopted as the alkali metal. Furthermore, the group-III metal may be gallium (Ga), boron (B), aluminum (Al), indium (In), and the like, and in the embodiment, Ga is adopted as the group-III metal.

In the embodiment, first in the alkali metal coating step S1, an Na material that is a solid alkali metal at room temperature is heated and melted to prepare alkali metal melt. Then, a predetermined amount of Na material is measured in a glove box, the atmosphere of which is controlled in terms of oxygen, dew point, and the like, and as illustrated in FIG. 2, the predetermined amount of Na material 11 is introduced in an empty crucible 10. Thereafter, the temperature of the crucible 10 is controlled to be lower than the melting point of Na to solidify the Na material 11 in the crucible. In this state, an upper surface 11a of the Na material 11 is located on the side of the opening of the crucible 10 and in a state of being exposed to ambient air. On the other hand, side surfaces 11b and a bottom surface 11c of the Na material 11 are in tight contact with inner surfaces in the crucible 10 over the entire area and are in a state of being unexposed to ambient air. At this stage, no additive element such as carbon is introduced.

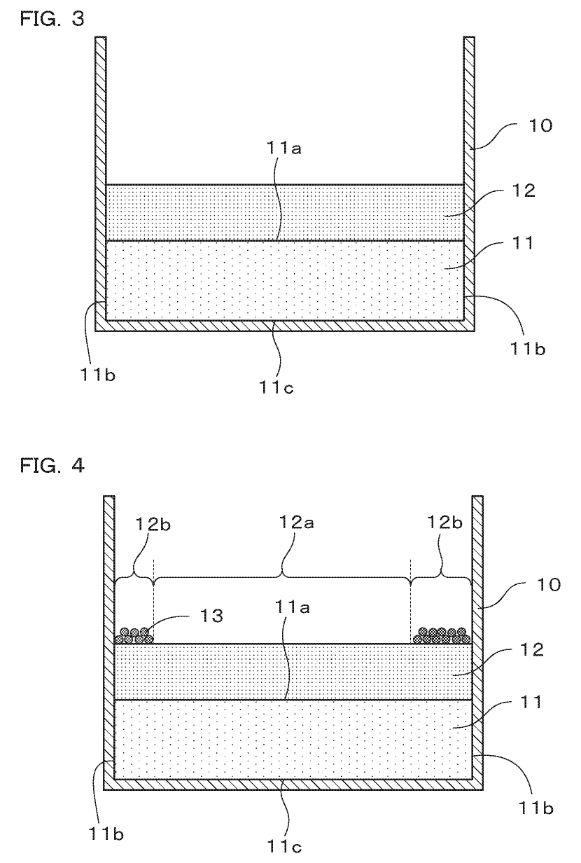

Next, a predetermined amount of solid Ga is added as the group-III metal over solidified Na material 11 in the crucible 10. The crucible 10 is controlled to a temperature higher than or equal to the melting point of Ga and lower than the melting point of Na to melt Ga without melting the Na material 11. In this way, Ga melt spreads over the upper surface 11a of the Na material 11, covering the upper surface 11a of the Na material 11, which is left exposed in the crucible 10, with Ga 12 as illustrated in FIG. 3. Here, since no additive element such as carbon is introduced in the Na material 11, a high wettability of the Na material 11 by melt of Ga 12 is maintained, and therefore, the melt of Ga 12 dynamically spreads over the entire area of the upper surface 11a of the Na material 11. Thereafter, the crucible 10 is controlled to a temperature lower than the melting point of Ga 12 to solidify Ga 12 over the entire area of the upper surface 11a of the Na material 11. Note that any additive element may be introduced into the melt of the Na material 11 to the extent that the wettability of the Na material 11 by the melt of Ga 12 does not decrease.

In the embodiment, while solid Ga is added onto the Na material 11 and then Ga 12 is melted, the melt of Ga 12 produced by melting Ga 12 beforehand may be added onto the Na material 11 instead. In this case, it is also possible to control the crucible 10 to a temperature higher than or equal to the melting point of Ga 12 and lower than the melting point of Na, and after the melt of Ga 12 spreads over the entire area of the upper surface 11a of the Na material 11, control the crucible 10 to a temperature lower than the melting point of Ga 12 to solidify Ga 12 over the entire area of the upper surface 11a of the Na material 11.

### 3. Carbon Addition Step S2

After the alkali metal coating step S1, the embodiment includes the carbon addition step S2 of adding carbon 13 into the crucible 10 as illustrated in FIG. 4. The addition of the carbon 13 produces effects of promoting crystal growth and reducing formation of defective crystals in the crystal growth step S4 described later. In the carbon addition step S2, the carbon 13 is added onto Ga 12 solidified in in the crucible 10. Furthermore, the carbon 13 may be added onto Ga 12 after the melt of Ga 12 is spread over the entire area of the upper surface 11a of the Na material 11 and before Ga 12 is solidified. There is no limitation on the amount of addition of the carbon 13, which may be set as necessary to the extent that effects of promoting crystal growth and reducing formation of defective crystals are produced.

The carbon 13 to be added in the carbon addition step S2 is preferably in powdered form. In the embodiment, the "powdered form" refers to what is in a solid state that has the length of the largest portion of less than or equal to 500 μm, although there is no limitation on the shape. The carbon 13 in powdered form enables the surface area of the carbon 13 to increase, so that it is further possible to improve effects of promoting crystal growth and reducing formation of defective crystals.

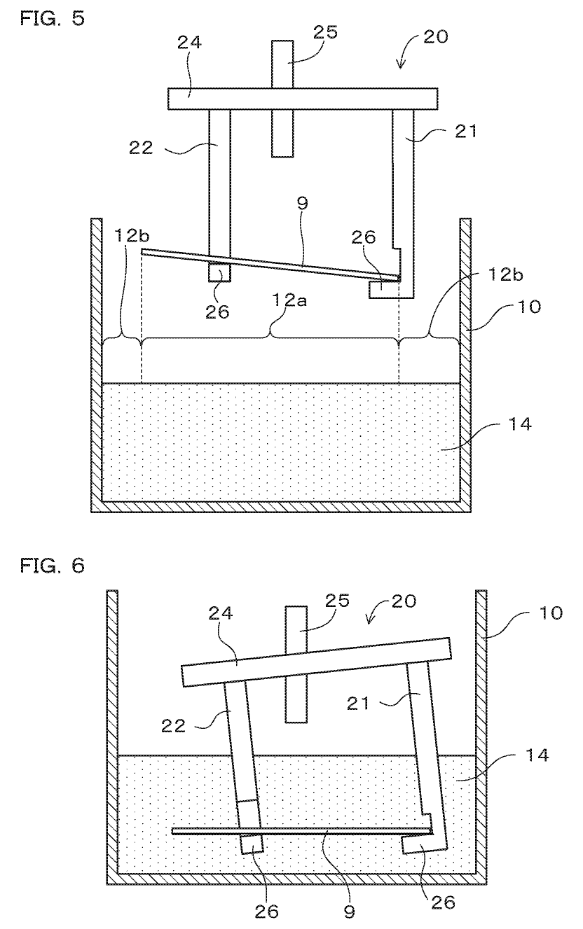

In the carbon addition step S2 of the embodiment, as illustrated in FIG. 4, the carbon 13 is added in the crucible 10 at a position 12b excluding a position 12a at which a seed substrate 9 in the crystal growth step S4 described later is to be immersed. In the embodiment, the position 12a at which the seed substrate 9 is to be immersed is referred to as a planned position for immersion, and the position 12b at which the carbon 13 is to be added is referred to as a carbon-adding position. As illustrated in FIGS. 5 to 7, the planned position for immersion 12a is a position that overlaps the seed substrate 9 when the crucible 10 is viewed from the side of the opening in the crystal growth step S4, and the carbon-adding position 12b is a position that does not overlap the seed substrate 9 when the crucible 10 is viewed from the side of the opening.

In the carbon addition step S2, if carbon is added at the planned position for immersion 12a, the carbon will undesirably be inhibited from dispersing into a mixed melt 14 because the carbon 13 penetrates between the back surface of the seed substrate 9 immersed in the mixed melt 14 in the crystal growth step S4 described later and the mixed melt 14. Accordingly, in the carbon addition step S2, adding the carbon 13 at the carbon-adding position 12b makes it possible to prevent that the carbon 13 is inhibited from dispersing into the mixed melt 14 in the crystal growth step S4. Note that, in the carbon addition step S2, any other elements may be added along with the carbon as required.

### 4. Mixed Melt Generation Step S3

As indicated in FIG. 1, the mixed melt generation step S3 is performed after the carbon addition step S2. In the mixed melt generation step S3, as illustrated in FIG. 4, the Na material 11, which corresponds to the alkali metal and is coated with Ga corresponding to the group-III metal, is melted along with the carbon 13 to generate the mixed melt 14 illustrated in FIG. 5. In the mixed melt generation step S3, the crucible 10 is controlled to a temperature higher than or equal to the melting point of Na and lower than the melting point of Na.

### 5. Crystal Growth Step S4

In the crystal growth step S4 indicated in FIG. 1, under an atmosphere containing nitrogen, the seed substrate 9 is immersed in the mixed melt 14 and a group-III nitride semiconductor is allowed to grow on the seed substrate 9 as illustrated in FIG. 6. In the embodiment, the crystal growth step S4 includes an initial nucleus forming step S41, a planarization step S42, and a film thickening step S43.

### 5-1. Initial Nucleus Forming Step S41

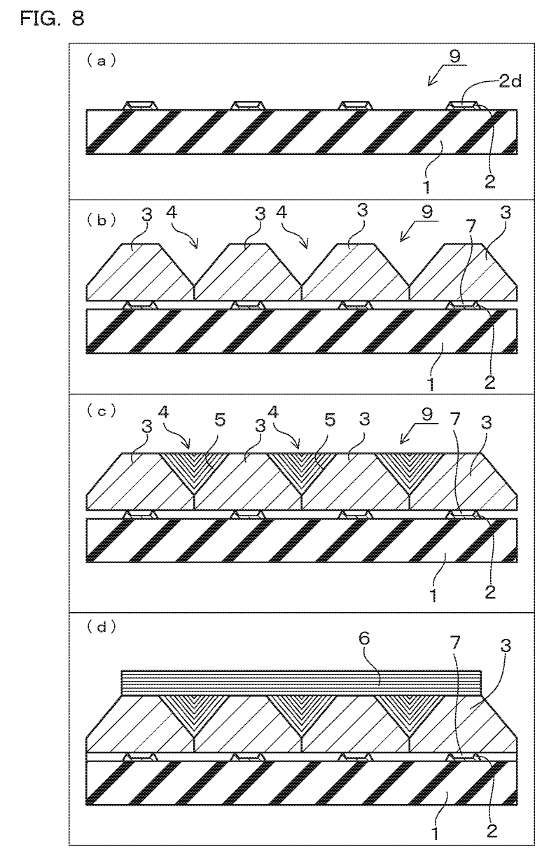

In the initial nucleus forming step S41, the seed substrate 9 illustrated in the part (a) of FIG. 8 is prepared. The seed substrate 9 is a multi-point seed (MPS) substrate, which is a substrate including a plurality of dot-shaped seed crystals 2 cyclically arranged on a substrate 1. The part (a) of FIG. 8 is a sectional view of the seed substrate 9 and shows a section that is perpendicular to the principal surface of the substrate. FIG. 4 is a plan view of the seed substrate 9 when it is viewed from above.

For the substrate 1, a group-III nitride semiconductor, sapphire, aluminum oxynitride, SiC, Si, spinel, ZnO, gallium oxide, and the like can be used. In the case of a sapphire substrate, for example, the principal surface of the substrate is a C-plane or an A-plane.

The plurality of seed crystals 2 are provided on the substrate 1 via a buffer layer (not illustrated). The seed crystals 2 are arranged in an equilateral triangular lattice pattern. The buffer layer and the seed crystal 2 are each a group-III nitride semiconductor that has any composition such as GaN, AlGaN, and AlN. The material of the buffer layer is selected appropriately depending on the material of the seed crystal 2. For example, in a case in which the seed crystal 2 is of GaN, the buffer layer is preferably of GaN. The material of the seed crystal is generally a group-III nitride semiconductor that has the same composition as that of a group-III nitride semiconductor intended to be grown by the flux method. The seed crystal 2 may be grown by any method such as an MOCVD method, an HVPE method, and an MBE method, whereas an MOCVD method and an HVPE method are preferable in terms of crystallinity and growth time.

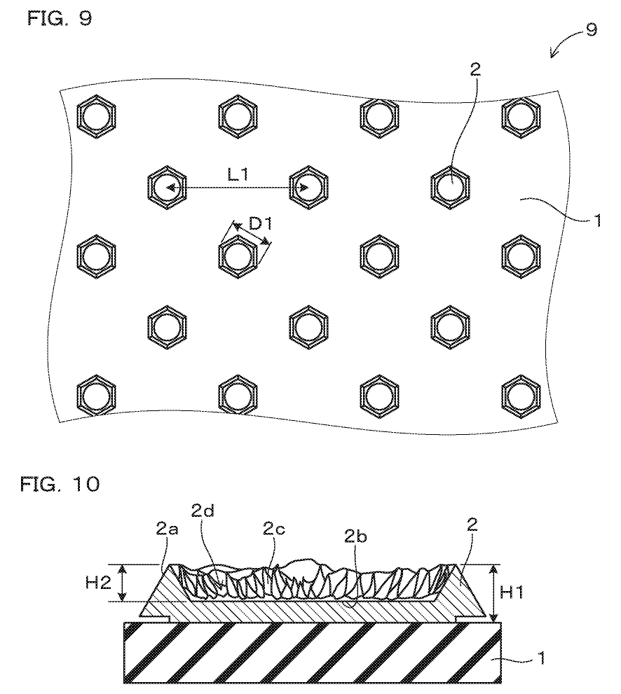

The arrangement of the seed crystals 2 is in an equilateral triangular lattice pattern as illustrated in FIG. 9. The shape of an equilateral triangular lattice is not a limitation, and any arrangement may be used to the extent that it has a cyclic arrangement, whereas a highly symmetric pattern such as a shape of a square lattice or an equilateral triangular lattice is preferable. It is possible to uniformly coalesce group-III nitride semiconductors grown from each of the seed crystals 2, so that it is possible to grow a group-III nitride semiconductor with less dislocation or warpage. When an equilateral triangular lattice pattern is chosen, the arrangement direction is preferably matched with the a-axis direction or the m-axis direction of the seed crystal 2. Here, to "match" does not mean perfect match and angular mismatch on the order of 10 degrees is allowable. Such angular mismatch is preferably less than or equal to one degree.

The distance L1 between centers of adjacent seed crystals 2 is preferably 100 to 2000 μm. In this range, it is possible to grow a group-III nitride semiconductor with less dislocation or warpage. The distance L1 is more preferably 200 to 1500 μm and further preferably 300 to 1000 μm.

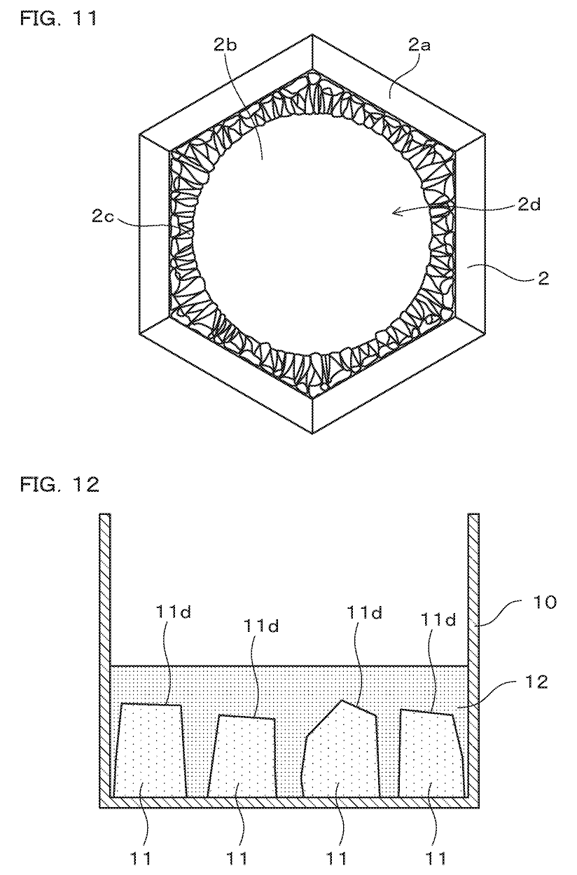

Next, the shape of the seed crystal 2 will be described in detail. FIG. 10 is a sectional view illustrating a configuration of the seed crystal 2 and is a sectional view that is perpendicular to the principal surface of the substrate. FIG. 11 is a plan view illustrating a configuration of the seed crystal 2. As illustrated in FIGS. 10 and 11, the seed crystal 2 includes a disc part that has a shape of a disc, and a truncated-regular-hexagonal-pyramid part that is located on and in contact with a circular columnar part and that has a shape of a truncated regular hexagonal pyramid, and is shaped with a recess 2d in the middle of the truncated-regular-hexagonal-pyramid part.

As described later, the seed crystal 2 is formed through selective growth using a mask and crystal growth is caused in the lateral direction from an opening of the mask. The pattern of the opening of the mask is circular. Consequently, a mask opening portion of a disc shape is left after removal of the mask. The remaining portion is the disc part. The shape of the disc part is equivalent to the shape of the mask opening for selective growth of the seed crystal 2. The diameter D1 of the truncated-regular-hexagonal-pyramid part is larger than the diameter of the disc part. Since the disc part is circular in plan view, it is possible to disperse stress when the substrate 1 is separated after a GaN single crystal is grown through the flux method, so that it is possible to reduce cracks in the grown crystal. While other shapes such as a regular hexagonal plate may be chosen in lieu of the disc part depending on the pattern of the opening of the mask, the disc is preferable in terms of dispersing the stress as described above.

The bottom surface of the truncated-regular-hexagonal-pyramid part of the seed crystal is a regular hexagon. In particular, each edge of the regular hexagon is preferably aligned with an M-plane of the seed crystal 2 (each edge is matched with the a-axis direction). Since the group-III nitride semiconductor is hexagonal, the regular hexagon makes it possible to uniformly coalesce group-III nitride semiconductors grown from the truncated-regular-hexagonal-pyramid part of each of the seed crystals 2. However, perfect match with the a-axis is not necessary and angular mismatch on the order of 10 degrees is allowable. Such angular mismatch is preferably less than or equal to one degree.

Each of six side surfaces 2a of the truncated-regular-hexagonal-pyramid part of the seed crystal 2 is a (10-11) plane of a group-III nitride semiconductor. The (10-11) plane is a stable plane in the mixed melt of the Na flux method. Accordingly, an initial nucleus 3 described later will grow while maintaining the (10-11) plane from a side surface 2a of the truncated-regular-hexagonal-pyramid part of the seed crystal 2. As a result, it is possible to make the shapes of the initial nuclei 3 uniform. Note that the side surface 2a is not necessarily the (10-11) plane entirely, whereas it is preferable that more than or equal to 95% of the entire side surface is the (10-11) plane. As the (10-11) plane referred to here, it is contemplated that a plane creating an angle of -5 to 5 degrees with respect to the (10-11) plane is included in the (10-11) plane as a deviation.

In the embodiment, the diameter D1 of the truncated-regular-hexagonal-pyramid part of the seed crystal 2 (the diameter of a circumcircle in plan view) is referred to as the diameter D1 of the seed crystal 2, and the diameter D1 of the seed crystal 2 is preferably 30 to 300 μm. In this range, it is possible to grow a group-III nitride semiconductor with less dislocation or warpage. Furthermore, it is possible to increase the surface area of the side surface 2a of the truncated-regular-hexagonal-pyramid part of the seed crystal 2, facilitating growth of the initial nucleus 3 from the side surface 2a. The diameter D1 of the seed crystal 2 is more preferably 100 to 200 μm.

The height H1 of the seed crystal 2 is preferably higher than or equal to 30 μm. In this range, a sufficiently large surface area of the side surface 2a can be secured, so that it is possible to uniformly grow the crystals from side surfaces 2a. As a result, it is possible to make the shapes of the initial nuclei 3 grown from each of the seed crystals 2 uniform. However, too great a height H1 poses a problem of long time required for forming the seed crystal 2, and therefore, H1 is preferably less than or equal to 100 μm. The height H1 is more preferably 20 to 60 μm and further preferably 30 to 50 μm.

For the same reason as above, the height H1 of the seed crystal 2 is preferably 0. 01 to 0. 6 times the diameter D1 of the seed crystal 2. The height H1 is more preferably 0. 1 to 0. 35 times and further preferably 0. 15 to 0. 3 times the diameter D1.

The recess 2d is provided in the middle of the seed crystal 2. With the recess 2d thus provided, as illustrated in the part (a) of FIG. 8 and the part (b) of FIG. 8, the recess 2d will not be filled with the initial nucleus 3 grown from the seed crystal 2 in the initial nucleus forming step S41 described later to form a void 7 (see FIG. 8). It is possible by the void 7 thus formed to prevent dislocation in the seed crystal 2 from propagating upward, and therefore, a high-quality GaN single crystal can be grown.

As illustrated in FIG. 10, the bottom surface 2b of the recess 2d is planar and is a (0001) plane (C-plane) of the group-III nitride semiconductor. Furthermore, the bottom surface 2b is substantially circular in plan view. Note that the bottom surface 2b is not necessarily planar and may have protrusions and indentations. Furthermore, the shape of the bottom surface 2b in plan view is not necessarily circular.

A number of protrusions and indentations are formed on a side surface 2c of the recess 2d, and the side surface 2c as a whole is inclined to the same extent as the (10-11) plane. The side surface 2c thus formed with protrusions and indentations allows the side surface 2c itself to serve as a starting point of crystal growth of the group-III nitride semiconductor, facilitating filling of an upper portion of the seed crystal 2 with the group-III nitride semiconductor. Note that the side surface 2c may be a planar surface.

The depth H2 of the recess 2d is preferably 10 to 100 μm. The range thus set facilitates formation of the void 7, so that it is possible to grow a more high-quality group-III nitride semiconductor. The depth H2 is more preferably 20 to 60 μm and further preferably 30 to 50 μm. Furthermore, for the same reason, the depth H2 of the recess 2d is preferably 0. 3 to 1. 0 times and more preferably 0. 6 to 0. 8 times the height H1 of the seed crystal 2.

The diameter of an upper surface of the recess 2d is in such a range that no upper surface is present in the seed crystal 2, and the side surface 2c of the recess 2d and the side surface 2a of the seed crystal 2 are angularly connected together. Consequently, there is no C-plane in an upper portion of the seed crystal 2. The C-plane can be melted back in the mixed melt of the Na flux method and cause variation in the shapes of initial nuclei 3. Furthermore, crystal growth from the C-plane can cause dislocation in the seed crystal 2 to propagate upward. Accordingly, the shape with no C-plane in the upper portion makes it possible to reduce variation in the shapes of initial nuclei 3 so that it is possible to reduce upward propagation of dislocation in the seed crystal 2.

The seed substrate 9 can be produced as described below, for example. First, a mask that has a plurality of openings is formed on the substrate 1. The plurality of openings are arranged in a pattern of an equilateral triangular lattice. The shape of the opening is circular. The shape may be any shape other than circular such as a regular hexagon, whereas a circular shape is preferable as in the embodiment to form the disc part such that cracks are reduced when the substrate is detached. Any material may be chosen for the mask to the extent that the material is capable of reducing growth of a group-III nitride semiconductor over the mask and is, for example, SiO₂.

Next, a buffer layer (not illustrated) and the seed crystal 2 are selectively grown in this order on the substrate exposed in the opening by a method such as an MOCVD method and an HVPE method. Next, the mask is removed by melt-back by using hydrofluoric acid and the like. As described above, the seed substrate 9 can be produced.

Here, when selectively growing the seed crystal 2 from the opening in the mask, facet growth of the group-III nitride semiconductor is caused by appropriately controlling growth conditions, making it possible for the shape of the seed crystal 2 to be the shapes illustrated in FIGS. 10 and 11. For example, the growth temperature may be 1120 to 1145°C and V/III ratio may be 970 to 120. Since the shape depends on selective growth, it is possible to make the shapes of the seed crystals 2 uniform.

Thereafter, in the initial nucleus forming step S41, the mixed melt 14 is brought into contact with the surface of the seed crystal 2 under an atmosphere containing nitrogen to form the initial nucleus 3 on each seed crystal 2 as illustrated in the part (b) of FIG. 8.

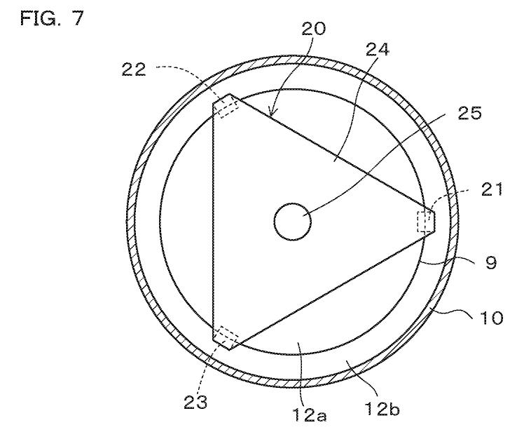

In the initial nucleus forming step S41, as illustrated in FIG. 6, the seed substrate 9 is first immersed in the mixed melt 14 produced in the crucible 10 by using a jig 20. As illustrated in FIGS. 5 to 7, the jig 20 is disposed inside the crucible 10 for growing a semiconductor single crystal by the flux method and can support the seed substrate 9 for growing a group-III nitride semiconductor single crystal inside the crucible 10. The jig 20 includes a first leg part 21, a second leg part 22, a third leg part 23, a connection part 24, and a lifting shaft 25. The material of each member of the jig 20 is alumina. As illustrated in FIGS. 5 to 7, the first leg part 21, the second leg part 22, and the third leg part 23 are each formed substantially in a rod shape, and as illustrated in FIG. 7, suspended from corners of the connection part 24, which is substantially triangular and has a flat-plate shape in plan view.

As illustrated in FIGS. 5 and 6, a substrate-supporting part 26 made up of a projection capable of supporting the seed substrate 9 is formed at a lower end of each of the first leg part 21, the second leg part 22, and the third leg part 23 illustrated in FIGS. 7. The first leg part 21 is formed as being longer than the second leg part 22 and the third leg part 23, which is not illustrated. In this way, the substrate 1 supported by the substrate-supporting part 26 is supported in a state of being inclined with respect to the connection part 24. The connection part 24 is connected to the lifting shaft 25 such that it can maintain an inclined attitude with respect to the lifting shaft 25. In this way, the seed substrate 9 supported by the substrate-supporting part 26 is inclined with respect to the horizontal as illustrated in FIG. 5 before being immersed in the mixed melt 14 stored in the crucible 10 and is horizontal as illustrated in FIG. 6 while being immersed in the mixed melt 14 stored in the crucible 10.

In the initial nucleus forming step S41, when the seed substrate 9 is to be immersed in the mixed melt 14 by using the jig 20, outgassing components such as oxygen in a furnace are sufficiently reduced by replacing the atmosphere in the furnace with inert gas, heating the inside of the furnace, and thereafter, establishing a vacuum. Next, the crucible 10 in which the raw material is placed and the seed substrate 9 are introduced into a reaction vessel and a vacuum is established, and thereafter, gas containing nitrogen is supplied to the reaction vessel. Once the pressure within the reaction vessel reaches a crystal growth pressure, the inside of the furnace is heated to a crystal growth temperature. The crystal growth temperature is, for example, higher than or equal to 700°C and lower than or equal to 1000°C, and the crystal growth pressure is, for example, higher than or equal to 2 MPa and lower than or equal to 10 MPa.

Once the crystal growth temperature and the crystal growth pressure are reached in the reaction vessel and nitrogen dissolved in the mixed melt 14 becomes supersaturated, the seed substrate 9 is immersed in the mixed melt 14 in the crucible 10 as illustrated in FIG. 6. Then, crystal (initial nucleus 3) of GaN grows from each seed crystal 2 on the seed substrate 9. The growth of the initial nucleus 3 continues until adjacent initial nuclei 3 start to coalesce together (see the part (b) of FIG. 8). Note that a gap remains between the initial nucleus 3 and the substrate 1.

Here, the (10-11) plane, which is the side surface 2a of the truncated-regular-hexagonal-pyramid part of the seed crystal 2, is stably present without being melted back in the mixed melt 14. Furthermore, the height H1 of the seed crystal 2 is higher than or equal to 30 μm and the side surface 2a has a sufficiently large surface area. Accordingly, the initial nucleus 3 grows while maintaining the (10-11) plane from the side surface 2a. The shapes of the seed crystals 2 are uniform and the initial nucleus 3 uniformly grows while maintaining the (10-11) plane from the seed crystal 2, and therefore, it is possible to reduce variation in the shapes of initial nuclei 3 and make the shapes of initial nuclei 3 uniform.

Furthermore, since the recess 2d is formed in the middle of seed crystal 2, the recess 2d is not completely filled with the initial nucleus 3 and the void 7 is formed. The mixed melt

14 is confined in the void 7. Since the void 7 is formed in an upper portion of the seed crystal 2, it is possible to reduce transfer of dislocation in the seed crystal 2 upward.

Furthermore, a large diameter of the recess 2d is secured to achieve the shape with no upper surface (C-plane) in the seed crystal 2. The C-plane can be melted back in the mixed melt 14 and is a surface that is not stable. Since crystal growth from such unstable surface is eliminated, it is further possible to reduce variation in the shapes of initial nuclei 3. Furthermore, since crystal growth from the C-plane is eliminated, it is further possible to reduce transfer of dislocation in the seed crystal 2 upward.

### 5-2. Planarization Step S42

Next, the planarization step S42 indicated in FIG. 1 is performed. The planarization step S42 is a step of causing crystal growth by using a flux-film coating (FFC) method and is a step of planarizing the crystal surface by repeating immersing the seed substrate 9 on which the initial nuclei 3 are formed in the mixed melt 14 stored in the crucible 10, pulling out and then heating the substrate under a nitrogen atmosphere, so that a GaN single crystal is caused to grow from the initial nucleus 3 to fill the GaN single crystal between adjacent initial nuclei 3.

In the FFC method in the planarization step S42 in Embodiment 1, removing the seed substrate 9 from the mixed melt 14 as illustrated in FIG. 5 and immersing it in the mixed melt 14 as illustrated in FIG. 6 are repeated in a predetermined cycle. As illustrated in the part (b) of FIG. 8, at the stage at which adjacent initial nuclei 3 start to coalesce together, a dent 4 is generated on the coalesced surface. When the seed substrate 9 is removed from the mixed melt 14, the mixed melt 14 is accumulated in the dent 4 between adjacent initial nuclei 3. This allows a crystal 5 to grow along the dent 4 (see the part (c) of FIG. 8).

Here, since the mixed melt 14 accumulated in the dent 4 is thin in its thickness, nitrogen easily becomes supersaturated. Accordingly, the rate of crystal growth can be increased. On the other hand, the amount of the accumulated mixed melt 14 is small, and therefore the amount of Ga is also small, so that crystal growth ceases after a while. Accordingly, the mixed melt 14 that contains Ga is intermittently supplied to the dent 4 by immersing the seed substrate 9 in the mixed melt 14 again as illustrated in FIG. 6 and removing the seed substrate 9 from the mixed melt 14 as illustrated in FIG. 5. The FFC method continues until the dent 4 is filled with the grown crystal 5. In this way, it is possible to grow a crystal that has a planar C-plane.

### 5-3. Film Thickening Step S43

As indicated in FIG. 1, the film thickening step S43 is performed after the planarization step S42. The film thickening step S43 is a step of forming a thickened group-III nitride single crystal (GaN single crystal) 6 on a GaN substrate (seed substrate 9) by immersing the GaN substrate, which is the seed substrate 9 that has a crystal surface planarized in the planarization step S42, in the mixed melt 14 of Ga and Na stored in the crucible 10.

In the film thickening step S43 in Embodiment 1, as illustrated in FIG. 8, the seed substrate 9 with a planar crystal surface is immersed in the mixed melt 14 in a state of being supported by the substrate-supporting part 26, and once the GaN single crystal 6 is grown to a desired thickness, the temperature is lowered to room temperature and the pressure is also lowered to normal pressure to terminate growth of the GaN single crystal 6. Note that the duration of the film thickening step S43 may be set as necessary depending on a target thickness of the GaN single crystal 6. Here, the gap between the initial nucleus 3 and the substrate 1 is left unfilled. This makes it possible to detach the substrate 1 spontaneously due to a difference in coefficient of thermal expansion when the temperature is lowered.

As described above, according to the method of growing a GaN single crystal in Embodiment 1, the side surface of the seed crystal 2 is made of a (10-11) plane. Accordingly, it is possible to reduce variation in the shapes of initial nuclei 3 and form a uniform and high-quality GaN single crystal 6.

Furthermore, the recess 2d is provided in the middle of the seed crystal 2, resulting in a shape with no upper surface. Accordingly, during growth of the initial nucleus 3, an upper portion of the seed crystal 2 is not filled and the void 7 is formed. As a result, it is possible to reduce upward propagation of dislocation in the seed crystal 2 and form a high-quality GaN single crystal 6.

Note that the planarization step S42 based on the FFC method in the embodiment is not necessarily essential, whereas the planarization step S42 is preferable in order to improve flatness of a crystal and further reduce warpage.

### 6. Advantageous Effects

Advantageous effects of a manufacturing method of a group-III nitride semiconductor in Embodiment 1 will now be described. In the manufacturing method of a group-III nitride semiconductor of Embodiment 1, the surface 11a of the solid alkali metal 11 is covered with Ga 12 that is a group-III metal, which is thereafter melted along with the carbon 13 to generate the mixed melt 14. Accordingly, wettability of the surface 11a of the solid alkali metal 11 by the melt of group-III metal 12 is maintained and the surface 11a of the alkali metal 11 is coated with Ga 12, so that the surface 11a of the alkali metal 11 is prevented from being exposed to ambient air. As a result, the surface 11a of the alkali metal 11 is prevented from reacting with oxygen, moisture, and the like in ambient air and it is possible to improve crystallinity of a formed group-III nitride semiconductor.

Furthermore, in the embodiment, the carbon 13 is in powdered form. Accordingly, the surface area of the carbon 13 increases such that dispersion into melt of the Na material 11 that is an alkali metal is facilitated, so that it is further possible to produce an effect of promoting crystal growth and an effect of reducing occurrence of defective crystals.

Furthermore, in the embodiment, the alkali metal coating step S1 includes bringing the crucible 10 in which a melt of the Na material 11 that is an alkali metal is stored to a temperature higher than or equal to the melting point of Ga 12 that is a group-III metal and lower than the melting point of the alkali metal 11 such that the alkali metal 11 is solidified in the crucible 10, and thereafter adding the group-III metal to the crucible 10 to coat the surface 11a of the solid alkali metal 11 with the melt of the Ga 12 that is a group-III metal. Accordingly, solidifying melt of the alkali metal 11 in the crucible 10 allows the upper surface 11a of surfaces of the solid alkali metal 11 to be a planar surface and makes it possible to cover the bottom surface 11c and the side surfaces 11b by an inner bottom surface and inner side surfaces of the crucible 10. Accordingly, simply covering the upper surface 11a of the solid alkali metal 11 with the group-III metal makes it possible to block the entire area of the surfaces 11a to 11c of the solid alkali metal 11 from ambient air such that the surfaces 11a to 11c of the alkali metal 11 are prevented from reacting with oxygen, moisture, and the like in the ambient air, so that it is further possible to reduce degradation of crystallinity of a formed group-III nitride semiconductor.

Furthermore, in the embodiment, the alkali metal coating step S1 includes adding the group-III metal 12 to the crucible 10 to coat the surface 11a of the alkali metal 11 of a solid form with the melt of group-III metal 12, and thereafter bringing the crucible 10 to a temperature lower than the melting point of the group-III metal 12 such that the group-III metal 12 coating the surface of the alkali metal 11 is solidified. Accordingly, the group-III metal 12 is solidified in a state in which the surfaces of the solid alkali metal 11 are coated with the melt of group-III metal 12 in the crucible 10, so that the surfaces 11a of the solid alkali metal 11 can be reliably coated and kept in a coated state.

Furthermore, in the embodiment, the carbon addition step S2 of adding the carbon 13 to the crucible 10 after the alkali metal coating step S1 is included, and the mixed melt generation step S3 is performed after the carbon addition step S2. Accordingly, the carbon 13 is added after the group-III metal 12 coating the surface 11a of the solid alkali metal 11 is solidified, and therefore, the wettability of the solid alkali metal 11 by the group-III metal 12 is not affected, so that the surface 11a of the solid alkali metal 11 can be reliably coated with the group-III metal 12 and kept in a coated state.

In the embodiment, in the carbon addition step S2, the carbon 13 is added in the crucible 10 at a position excluding a position 12a at which the seed substrate 9 is to be immersed. Accordingly, when the seed substrate 9 is to be immersed in the mixed melt 14, it is possible to facilitate dispersion of the carbon 13 into the mixed melt 14, so that it is further possible to produce an effect of promoting crystal growth and an effect of reducing occurrence of defective crystals.

In the embodiment, as illustrated in FIG. 3, in the alkali metal coating step S1, alkali metal melt resulting from heating and melting the Na material 11 is solidified in the crucible 10, and thereafter, the upper surface 11a of the solid Na material 11 is covered with the melt of group-III metal. Alternatively, as in the modification illustrated in FIG. 12, a surface 11d of the solid Na material 11 may be covered with the melt of group-III metal in a state in which the solid Na material 11 is introduced in the crucible 10. In this case, among the surfaces 11d of the solid Na material 11, the group-III metal 12 covers all the surfaces 11d excluding portions in contact with the crucible 10. In the modification, advantageous effects equivalent to those of Embodiment 1 are also produced.

As described above, according to the above-described embodiment and modification, it is possible to provide a manufacturing method of a group-III nitride semiconductor capable of improving crystallinity.

The present invention is not limited to the above-described embodiment and modification and may be applied to various embodiments without departing from the scope of the invention.

What is claimed is:

1. A manufacturing method of a group-III nitride semiconductor, the method comprising:
an alkali metal coating step of covering a surface of an alkali metal of a solid form with a group-III metal;
a mixed melt generation step of melting the alkali metal coated with the group-III metal along with carbon to generate a mixed melt; and
a crystal growth step of immersing a seed substrate in the mixed melt to grow a group-III nitride semiconductor on the seed substrate under an atmosphere containing nitrogen.

2. The manufacturing method of a group-III nitride semiconductor according to claim 1, wherein the carbon is in powdered form.

3. The manufacturing method of a group-III nitride semiconductor according to claim 1, wherein the alkali metal coating step includes bringing a crucible in which a melt of the alkali metal is stored to a temperature higher than or equal to a melting point of the group-III metal and lower than a melting point of the alkali metal such that the alkali metal is solidified in the crucible, and thereafter adding the group-III metal to the crucible to coat a surface of the alkali metal of a solid form with a melt of the group-III metal.

4. The manufacturing method of a group-III nitride semiconductor according to claim 3, wherein the alkali metal coating step includes adding the group-III metal to the crucible to coat a surface of the alkali metal of a solid form with the melt of the group-III metal, and thereafter bringing the crucible to a temperature lower than a melting point of the group-III metal such that the group-III metal coating the surface of the alkali metal is solidified.

5. The manufacturing method of a group-III nitride semiconductor according to claim 4, further comprising
a carbon addition step of adding carbon to the crucible after the alkali metal coating step, wherein
the mixed melt generation step is performed after the carbon addition step.

6. The manufacturing method of a group-III nitride semiconductor according to claim 5, wherein in the carbon addition step, the carbon is added in the mixed melt in the crucible at a position excluding a position at which the seed substrate is to be immersed.
